(19) United States
(12) Patent Application Publication
(10) Pub. No.: US 2025/0323087 A1
(43) Pub. Date: Oct. 16, 2025

(54) SUBSTRATE PROCESSING APPARATUS

(71) Applicant: SAMSUNG ELECTRONICS CO., LTD., Suwon-si (KR)

(72) Inventors: Jongwon Lee, Suwon-si (KR); Junho Lee, Suwon-si (KR); Jihoon Jeong, Suwon-si (KR); Taeheon Kim, Suwon-si (KR); Sungjun Noh, Suwon-si (KR); Younghoo Kim, Suwon-si (KR); Junho Yoon, Suwon-si (KR); Jiwoong Jung, Suwon-si (KR); Jeonghwa Hong, Suwon-si (KR)

(73) Assignee: SAMSUNG ELECTRONICS CO., LTD., Suwon-si (KR)

(21) Appl. No.: 19/018,524

(22) Filed: Jan. 13, 2025

(30) Foreign Application Priority Data
Apr. 12, 2024 (KR) 10-2024-0049431

(51) Int. Cl. H01L 21/687; H01L 21/67

(52) U.S. Cl. CPC H01L 21/68792; H01L 21/67034

(57) ABSTRACT

Provided is a substrate processing apparatus including a processing container including an upper container, a lower container, and a processing space formed inside the upper container and the lower container, support pins, a block plate having an upper surface on which the support pins are provided, a plate support provided in the lower container and configured to support a lower surface of the block plate, and a fluid supply device, wherein a chamber lower surface of the lower container in contact with the processing space includes a first surface, a first tilted surface, and a second surface extending sequentially from a center of the processing space, a vertical level of the second surface is higher than a vertical level of the first surface, and a first tilt angle formed between the first tilted surface and the first surface is an acute angle.

### CROSS-REFERENCE TO RELATED APPLICATION

This application claims priority to Korean Patent Application No. 10-2024-0049431, filed on Apr. 12, 2024, in the Korean Intellectual Property Office, the disclosure of which is incorporated by reference herein in its entirety.

### BACKGROUND

### 1. Field

One or more embodiments of the present disclosure relate to a substrate processing apparatus, and more particularly, to a substrate processing apparatus that performs a drying process using supercritical fluid.

### 2. Description of Related Art

As manufacturing dimensions for integrated circuit devices decrease, critical dimensions of semiconductor devices decrease to be between about 20 nm and about 30 nm, and accordingly, a process is performed to form deep and narrow patterns with a relatively large aspect ratio of about 5 or more. Accordingly, suitable cleaning and drying processes are required for patterns with a relatively large aspect ratio and a relatively fine critical dimension, and thus, cleaning and drying methods using supercritical fluid with a relatively small surface tension are proposed. However, while pressurizing the fluid in the drying process using supercritical fluid, the patterns on substrates collapse or are damaged due to turbulence of the fluid in some regions of wafers.

### SUMMARY

One or more embodiments provide a substrate processing apparatus that reduces damage of patterns of semiconductor wafers in a supercritical drying process.

According to an aspect of one or more embodiments, there is provided a substrate processing apparatus including a processing container including an upper container, a lower container, and a processing space inside the upper container and the lower container, a support pin in the processing space and configured to support a substrate, a block plate including an upper surface, the support pin being on the upper surface of the block plate, a plate support in the lower container and configured to support a lower surface of the block plate opposite to the upper surface of the block plate, a first conduit line in the upper container, a second conduit line in the lower container, and a fluid supply device configured to supply processing fluid in a supercritical state to the processing space through the first conduit line, wherein a chamber lower surface of the lower container, in contact with the processing space, includes a first surface, a first tilted surface, and a second surface extending sequentially from a center of the processing space, wherein a vertical level of the second surface is higher than a vertical level of the first surface, and wherein a first tilt angle between the first tilted surface and the first surface is an acute angle.

According to another aspect of one or more embodiments, there is provided a substrate processing apparatus including a processing container including an upper container, a lower container, and a processing space inside the upper container and the lower container, a support pin in the processing space and configured to support a substrate, a block plate including an upper surface, the support pin being on the upper surface of the block plate, a plate support in the lower container and configured to support a lower surface of the block plate opposite to the upper surface of the block plate, a first conduit line in the upper container, a second conduit line in the lower container, and a fluid supply device configured to supply processing fluid in a supercritical state to the processing space through the first conduit line, wherein a chamber lower surface of the lower container, in contact with the processing space, includes a first surface, a first tilted surface, and a second surface extending sequentially from a center of the processing space, wherein a vertical level of the second surface is higher than a vertical level of the first surface, wherein a first tilt angle between the first tilted surface and a horizontal surface is an acute angle, and wherein the first tilted surface is farther from a center of the lower container than the plate support.

According to still another aspect of one or more embodiments, there is provided a substrate processing apparatus including a processing container including an upper container, a lower container, and a processing space inside the upper container and the lower container, a support pin in the processing space and configured to support a substrate, a block plate including an upper surface, the support pin being on the upper surface of the block plate, a plate support in the lower container and configured to support a lower surface of the block plate opposite to the upper surface of the block plate, a first conduit line in the upper container, a second conduit line in the lower container, a fluid supply device configured to supply processing fluid in a supercritical state to the processing space through the first conduit line, and an upper substrate support in the upper container and configured to support a side portion of the substrate, wherein a chamber lower surface of the lower container, in contact with the processing space, includes a first surface, a first tilted surface, a second surface, a second tilted surface, and a third surface extending sequentially from a center of the processing space, wherein a vertical level of the second surface is higher than a vertical level of the first surface, wherein a first tilt angle between the first tilted surface and the first surface is an acute angle, and an angle between the second tilted surface and the second surface is an acute angle, wherein a distance between the plate support and a first center line is less than a first radius, the first center line being a virtual line vertically extending from a center of the upper container to a center line of the lower container, wherein the first radius is a radius from the first center line to a first connection point in which the first surface contacts the first tilted surface, wherein a second radius is less than a radius of the block plate, wherein the second radius is a radius from the first center line to a second connection point where the first tilted surface contacts the second surface, wherein the first surface, the second surface, and the third surface are parallel to each other, wherein the plate support is integrated with the lower container, wherein the first tilt angle is greater than a first reference angle, wherein the first reference angle between the first surface and an extension line extending from the plate support to an outer diameter of the block plate is an acute angle, and wherein the first conduit line and the second conduit line are respectively at a center of the upper container and a center of the lower container and are on a same line.

### BRIEF DESCRIPTION OF DRAWINGS

Embodiments will be more clearly understood from the following detailed description taken in conjunction with the accompanying drawings in which:

FIG. 1 is a cross-sectional view illustrating a substrate processing apparatus according to one or more embodiments;

FIG. 2A is an enlarged cross-sectional view of a part of FIG. 1;

FIG. 2B is a cross-sectional view schematically illustrating a direction, in which fluid flows, in a part of the substrate processing apparatus illustrated in FIG. 2A;

FIG. 3 illustrates simulation results depending on sizes of the first tilt angle of a substrate processing apparatus according to one or more embodiments;

FIG. 4 is a graph illustrating shear stresses, which are obtained from the simulation result of FIG. 3, in an edge region of a substrate depending on sizes of the first tilt angle;

FIG. 5 is a graph illustrating a difference between the greatest value and an average value of the shear stresses in the edge region of the substrate according to the size of the first tilt angle obtained from the simulation result of FIG. 3;

FIG. 6A illustrates simulation results depending on sizes of a first radius of a substrate processing apparatus according to one or more embodiments;

FIG. 6B illustrates simulation results depending on sizes of a first radius of a substrate processing apparatus according to one or more embodiments;

FIG. 7 is a graph illustrating shear stresses in an edge region of a substrate depending on sizes of the first radius obtained from the simulation results of FIGS. 6A and 6B;

FIG. 8 is a graph illustrating a difference between the greatest value and an average value of shear stresses in an edge region of a substrate depending on sizes of the first radius obtained from the simulation result of FIG. 3;

FIG. 9 is an enlarged cross-sectional view of a part of a substrate processing apparatus according to one or more embodiments;

FIG. 10 is an enlarged cross-sectional view of a part of a substrate processing apparatus according to one or more embodiments;

FIG. 11 illustrates simulation results for comparing a flow when a block plate is fixed with a flow when the block plate deviates from a normal position; and

FIG. 12 is a graph illustrating a shear stress acting on a front surface of a wafer which is obtained from the simulation result of FIG. 11.

### DETAILED DESCRIPTION

Hereinafter, embodiments are described in detail with reference to the attached drawings. Embodiments described herein are example embodiments, and thus, the disclosure is not limited thereto.

Embodiments are provided to more completely describe the present disclosure to those skilled in the art, following embodiments may be modified into various other forms, and the inventive concept is not limited to the following embodiments. A thickness and size of each layer in the drawings are exaggerated for the sake of convenience and clarity of description.

It will be understood that the first direction refers to the X direction, the second direction refers to the Y direction, and the first direction may be perpendicular to the second direction. The third direction is the Z direction, and the third direction may be perpendicular to the first direction and the second direction. A horizontal plane or a plane refers to an X-Y plane. An upper surface of a certain object refers to a surface in a positive third direction with respect to the certain object, and a lower surface of a certain object refers to a surface in a negative third direction with respect to the certain object.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

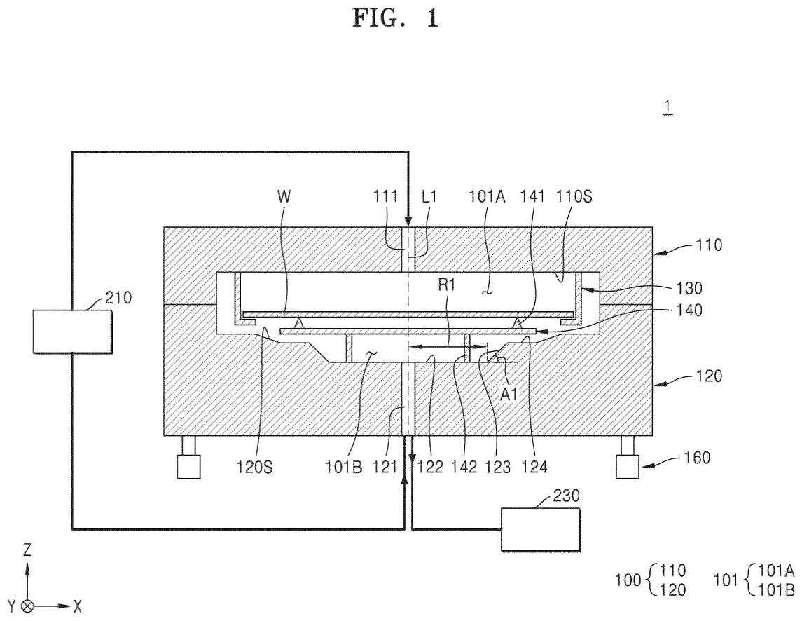

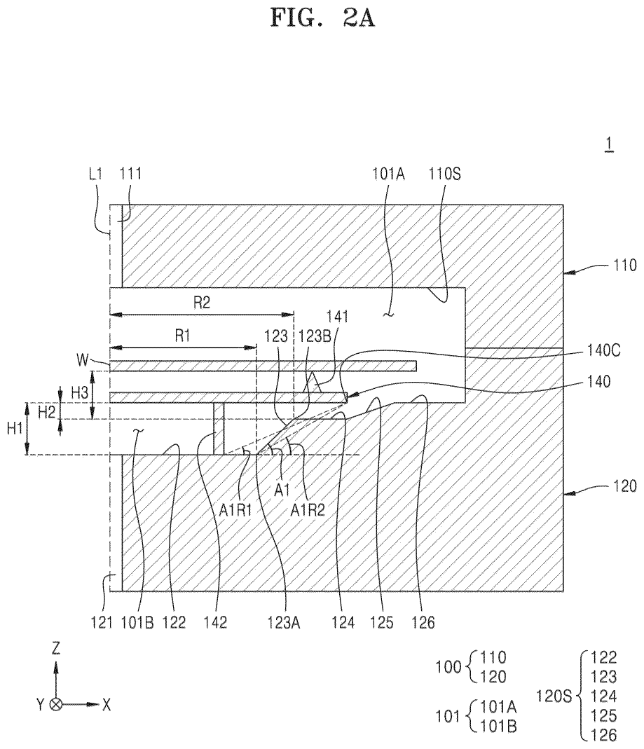

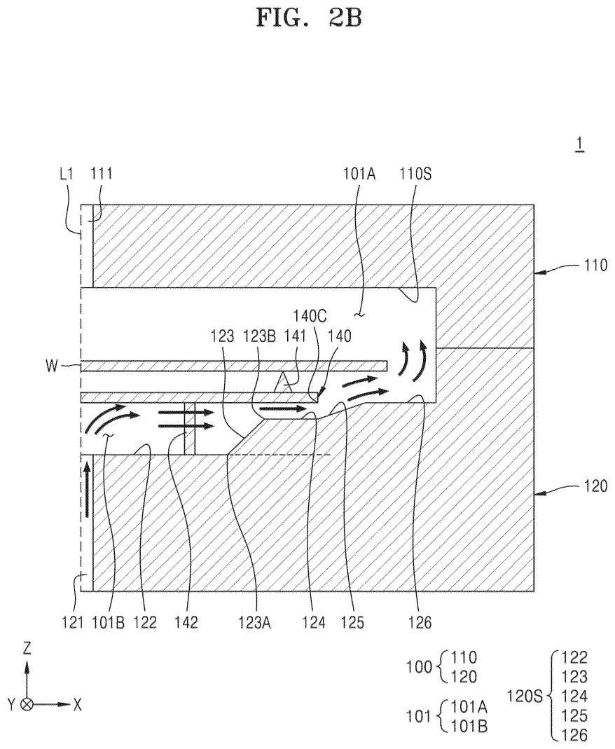

FIG. 1 is a cross-sectional view illustrating a substrate processing apparatus 1 according to one or more embodiments. FIG. 2A is an enlarged cross-sectional view of a part of FIG. 1. FIG. 2B is a cross-sectional view schematically illustrating a direction, in which fluid flows, in a part of the substrate processing apparatus 1 illustrated in FIG. 2A.

Referring to FIGS. 1 to 2B, the substrate processing apparatus 1 includes an upper container 110, a lower container 120, a block plate 140, support pins 141, a plate support 142, a first conduit line 111, a second conduit line 121, a fluid supply device 210, and an exhaust device 230.

A processing container 100 may have a processing space 101 in which a substrate W is processed. The processing container 100 may include the upper container 110 and a lower container 120. The processing space 101 may be provided inside the upper container 110 and the lower container 120. For example, the upper container 110 and the lower container 120 may be engaged with each other from above and below to form the processing space 101 in the processing container 100.

The processing space 101 may include an upper processing space 101A and a lower processing space 101B. The upper processing space 101A may be a part of the processing space 101 located above the substrate W, and the lower processing space 101B may be a part of the processing space 101 located below the substrate W.

The processing container 100 may seal the processing space 101 from the outside while processing the substrate W. In one or more embodiments, the processing space 101 may have a symmetrical shape with respect to a virtual first center line L1 of the processing container 100. For example, the processing space 101 may have a rotationally symmetrical shape with respect to the first center line L1 of the processing container 100. For example, the processing container 100 and the processing space 101 may each have a symmetrical shape with respect to a certain reference plane or a mirror shape.

The upper container 110 may be on the lower container 120. The upper container 110 and the lower container 120 may each include, for example, a metal material. For example, the upper container 110 may be coupled to and contact the lower container 120 to cover a space provided by the lower container 120. The upper container 110 and the lower container 120 may be switched between a closed position where the processing space 101 is sealed, and an open position where the processing space 101 is open to the atmosphere outside the processing space 101. In the closed position of the processing space 101, the upper container 110 may be coupled to and contact the lower container 120 to seal the processing space 101. In the open position of the processing space 101, the upper container 110 is spaced apart from the lower container 120, and the processing space 101 may be open to the atmosphere outside the processing space 101. The switching between the closed position and the open position of the processing space 101 may be implemented by a lifting device configured to move the upper container 110 in a direction (for example, the Z direction) perpendicular to the lower container 120.

The upper container 110 and the lower container 120 may be relatively moved by a drive mechanism 160, thereby being coupled to and connected to each other to switch between a closed position where the chamber is sealed, and an open position where the chamber is open. The upper container 110 and the lower container 120 may be coupled to or separated from each other by moving up and down along the lifting device provided between the upper container 110 and the lower container 120. In the open position of the chamber, the substrate W may be loaded into the processing space 101, or the substrate W may be unloaded from the processing space 101 to the outside.

The upper substrate support 130 may be provided in the processing space 101 and support the substrate W. The upper substrate support 130 may support the substrate W such that an upper surface of the substrate W faces an upper surface of the processing container 100 and a lower surface of the substrate W faces a bottom surface of the processing container 100. The upper surface of the substrate W may be a target surface that is processed by the substrate processing apparatus 1. The upper substrate support 130 may support the substrate W such that the center of the upper surface of the substrate W is aligned with the first center line L1 of the processing container 100. In FIGS. 2A and 2B, the upper substrate support 130 is omitted.

The upper substrate support 130 is provided on a chamber upper surface 110S of the processing container 100 and may support a side portion of the substrate W. For example, the upper substrate support 130 may include a vertical rod extending downward from an upper surface of the processing container 100, and a horizontal rod extending in a horizontal direction (for example, the X direction and/or Y direction) from one end of the vertical rod. The horizontal rod may be in contact with and support an outer region of a lower surface of the substrate W. For example, the upper substrate support 130 may be fixed to the upper container 110 to more stably support the substrate W while the upper container 110 is lifted or lowered.

The upper substrate support 130 may be configured to support a partial region of an outer edge of the substrate W, rather than supporting the entire outer edge of the substrate W. Accordingly, the simulation result of the substrate processing apparatus 1 described below is obtained based on a portion of the upper substrate support 130, which does not appear in a cross-section.

The fluid supply device 210 may generate processing fluid for processing the substrate W and supply the generated processing fluid to the processing space 101 of the processing container 100. In one or more embodiments, the fluid supply device 210 may be configured to generate and supply supercritical fluid, and the substrate processing apparatus 1 may be configured to process the substrate W by using the supercritical fluid. For example, the substrate processing apparatus 1 may be configured to perform a drying process on the substrate W by using the supercritical fluid.

The supercritical fluid may continuously change in physical property, such as density, viscosity, diffusion coefficient, and polarity, from a gas-like state to a liquid-like state according to a change in pressure. The supercritical fluid is a material that has a temperature above a critical temperature and a pressure above a critical pressure and may have diffusivity, viscosity, and surface tension similar to a gas and may also have solubility similar to liquid. When performing a drying process on the substrate W by using supercritical fluid, the supercritical fluid, which has almost no surface tension, may penetrate into a fine groove in the substrate W and dry cleaning liquid and/or rinse liquid on the substrate W while preventing leaning or water spots from being generated on the substrate W.

For example, the supercritical fluid may include carbon dioxide (CO₂), water (H₂O), methane (CH₄), ethane (C₂H₆), propane (C₃H₈), ethylene (C₂H₄), propylene (C₂H₂), methanol (C₂H₃OH), ethanol (C₂H₅OH), sulfur hexafluoride (SF₆), acetone (C₃H₈O), or a combination thereof. In one or more embodiments, the fluid supply device 210 may be configured to generate and supply supercritical fluid including carbon dioxide. The carbon dioxide may have a relatively low critical temperature of about 31° C. and a relatively low critical pressure of about 73 bar and may be non-toxic, non-flammable, and relatively inexpensive, thereby, being more easily used for drying the substrate W.

The fluid supply device 210 may be configured to supply processing fluid to the processing space 101 of the processing container 100 through at least one of the second conduit line 121 on a chamber lower surface 120S of the lower container 120 and the first conduit line 111 on the chamber upper surface 1105 of the upper container 110. The second conduit line 121 may extend from the chamber lower surface 120S of the lower container 120. The second conduit line 121 may extend downward from the chamber lower surface 120S of the lower container 120.

The first conduit line 111 and the second conduit line 121 may be provided on the first center line L1 described above. As described above, the processing space 101 has a symmetrical shape with respect to the first center line L1, and accordingly, the first conduit line 111 and the second conduit line 121 may be on the first center line L1 to obtain a relatively homogeneous flow distribution of the processing fluid for the substrate W.

The processing fluid may be supplied to the processing space 101 of the processing container 100 through the second conduit line 121, or the waste fluid may be discharged through the second conduit line 121. Here, the waste fluid may be defined as fluid including various gases, chemicals, by-products, particles, processing fluid, etc. in the processing space 101. The waste fluid may be discharged from a processing space through the second conduit line 121. The exhaust device 230 may include a vacuum pump, a recovery unit for recovering waste fluid, an on/off valve, a flow meter, etc. For example, an exhaust operation may be performed through the vacuum pump included in the exhaust device 230, and the exhaust device 230 may be configured to control the pressure in the processing space 101 by suctioning and removing waste fluid in the processing space 101.

Referring to FIG. 2A, the chamber lower surface 120S may include a first surface 122, a first tilted surface 123, a second surface 124, a second tilted surface 125, and a third surface 126, which extend outward from the center of the lower container 120 and are located in that order. For example, the first surface 122, the first tilted surface 123, the second surface 124, the second tilted surface 125, and the third surface 126 may be provided in the order in which a radius increases as the chamber lower surface 120S moves away from the second conduit line 121.

The first surface 122 may be parallel to the substrate W at the bottom of the block plate 140. The first surface 122 may be located at the center of the lower container 120, and the second conduit line 121 may be located at the center of the first surface 122. The first tilted surface 123 may be a part of the chamber lower surface 120S that is tilted to rise from the first surface 122 toward the outside. The second surface 124, in which the tilt of the first tilted surface 123 is not maintained, may extend from the first tilted surface 123 to be parallel to the substrate W. A point where the first surface 122 meets (contacts) the first titled surface 123 may be referred to as a first connection point 123A, and a point where the first tilted surface 123 meets (contacts) the second surface 124 may be referred to as a second connection point 123B. A distance from the first center line L1 to the first connection point 123A is less than a distance from the first center line L1 to the second connection point 123B.

A first radius R1, which is a distance from the first center line L1 to the first connection point 123A, may be greater than a distance from the first center line L1 to the plate support 142. The first radius R1 may also be less than a distance from the first center line L1 to an outer diameter of the block plate 140, for example, a radius of the block plate 140. However, embodiments are not limited thereto, and, for example, the first radius R1, which is the distance from the first center line L1 to the first connection point 123A, may be about 60 mm to about 95 mm.

A second radius R2, which is a distance from the first center line L1 to the second connection point 123B, may be less than the distance from the first center line L1 to the outer diameter of the block plate 140, that is, the radius of the block plate 140. The first radius R1 and the second radius R2 are described below in the description of a fluid simulation result.

A first tilt angle A1, which is a tilt angle based on the first surface 122 of the first tilted surface 123, may be an acute angle. For example, the first tilted surface 123 may not be perpendicular to the first surface 122. Also, a vertical level of the second surface 124 may be higher than a vertical level of the first surface 122 in the third direction (Z direction). Accordingly, the first tilted surface 123 extending the first surface 122 and the second surface 124 may be at a vertical level higher than a vertical level of the first surface 122.

The first tilt angle A1 may be equal to or greater than a first reference angle A1R1 or a second reference angle A1R2. The first reference angle A1R1 is an angle when the size of the first tilt angle A1 is the smallest, and is an angle between an extension line connecting a point where the first surface 122 is in contact with one end of the plate support 142 to an outer edge of the block plate 140 and a surface from which the first surface 122 extends in the first direction (X direction). The second reference angle A1R2 is an angle between an extension line connecting the first connection point 123A to an outer edge of the block plate 140 and a surface from which the first surface 122 extends in the first direction (X direction).

The first tilt angle A1 may be equal to or greater than the first reference angle A1R1. Therefore, when the first connection point 123A is at a lower end of the plate support 142 and the first tilted surface 123 starts from a point where the plate support 142 meets (contacts) the first surface 122, the first tilt angle A1, which is an angle of the first tilted surface 123, is equal to or greater than the first reference angle A1R1. Accordingly, an extension line extending from the first tilted surface 123 may meet (contact) the block plate 140.

When the first connection point 123A is at a lower end of the plate support 142, the first tilt angle A1 is equal to or greater than the first reference angle A1R1. Accordingly, the second connection point 123B, where the first tilted surface 123 ends, may be located to be closer to the first center line L1 than the block plate 140.

When the first connection point 123A is at a lower end of the plate support 142 and the first tilt angle A1 is less than the first reference angle A1R1, the second connection point 123B may be located outside an outer diameter of the block plate 140, and the second surface 124 extending from the second connection point 123B may be located outside a radius of the block plate 140. In contrast to this, the substrate processing apparatus 1 according to one or more embodiments has at least a part of the second surface 124 located at a position closer to the first center line L1 than a radius of the block plate 140 from the first center line L1.

The first tilt angle A1 may be equal to or greater than the second reference angle A1R2. Accordingly, when the first connection point 123A is located outside the plate support 142 and closer to the center than an outer diameter of the block plate 140 based on the first center line L1, an extension line extending from the first tilted surface 123 may meet (contact) the block plate 140 because the first tilted angle A1 is equal to or greater than the second reference angle A1R2.

When the first connection point 123A is located outside the plate support 142 and closer to the center than the outer diameter of the block plate 140 based on the first center line L1, the second connection point 123B where the first tilted surface 123 ends is closer to the first center line L1 than the block plate 140 because the first tilt angle A1 is equal to or greater than the second reference angle A1R2.

When the first connection point 123A is located outside the plate support 142 based on the first center line L1 and the first tilt angle A1 is less than the second reference angle A1R2, the second connection point 123B may be located outside the outer diameter of the block plate 140, and the second surface 124 extending from the second connection point 123B may be located outside a radius of the block plate 140. In contrast to this, the substrate processing apparatus 1 according to one or more embodiments has at least a part of the second surface 124 located at a position closer to the first center line L1 than a radius of the block plate 140 from the first center line L1. The first tilt angle A1 is described below in the description of a fluid simulation result.

The second tilted surface 125 may extend from the second surface 124 and have a second tilt angle, which is an angle formed with the second tilted surface 125 based on a surface from which the second surface 124 extends in the first direction (X direction). The second tilted surface 125 may extend from the second surface 124 and the third surface 126 located outside the second tilted surface 125 based on the first center line L1. The second tilt angle may be less than the first tilt angle A1. The third surface 126 extending from the second tilted surface 125 may be located outside the second tilted surface 125. The second tilted surface 125 and the third surface 126 may be located such that a distance between a part of the substrate W located outside an outer edge of the block plate 140 and the chamber lower surface 120S is not excessive and less than a predetermined value.

The first surface 122 may be parallel to the second surface 124. However, embodiments are not limited thereto, and, for example, the first surface 122, the second surface 124, and the substrate W placed on the support pins 141 on the block plate 140 may be parallel to each other. As another example, the first surface 122, the second surface 124, and the third surface 126 may be parallel to each other. As yet another example, the first surface 122, the second surface 124, the third surface 126, and the substrate W placed on the support pins 141 on the block plate 140 may be parallel to each other.

As illustrated in FIG. 2A, a first height H1, which is a vertical distance between the first surface 122 and a lower surface of the block plate 140, is greater than a second height H2 which is a vertical distance between the second surface 124 and the lower surface of the block plate 140. A third height H3, which is a vertical distance between the second surface 124 and a lower surface of the substrate W, is greater than the second height H2.

The second height H2 may be 0.1 to 0.25 times the first height H1, and the third height H3 may be 5 to 8 times the second height H2. Because the second height H2 is less than the first height H1 and the third height H3, a flow speed and flow rate of the processing fluid flowing from the upper processing space 101A to the lower processing space 101B are limited, and accordingly, vortex in an edge region of the substrate W may be reduced.

FIG. 2B schematically illustrates a fluid flow when the processing fluid is supplied through the second conduit line 121 and the processing fluid does not flow through the first conduit line 111 because the first conduit line 111 is closed. Fluid simulation results of the substrate processing apparatus 1 according to one or more embodiments, which are described below, are obtained by performing a simulation under the assumption that processing fluid is supplied through the second pipe 121 and the processing fluid does not flow through the first conduit line 111 because the first conduit line 111 is closed. For example, FIG. 2B illustrates a fluid flow under the assumption that the fluid supply device 210 supplies processing fluid and pressurizes the processing space 101 to cause the processing fluid to be in a supercritical state. Small arrows indicating a flow of the fluid illustrated in simulation pictures may be different in directions from arrows indicating a flow direction of the fluid schematically illustrated in FIG. 2B.

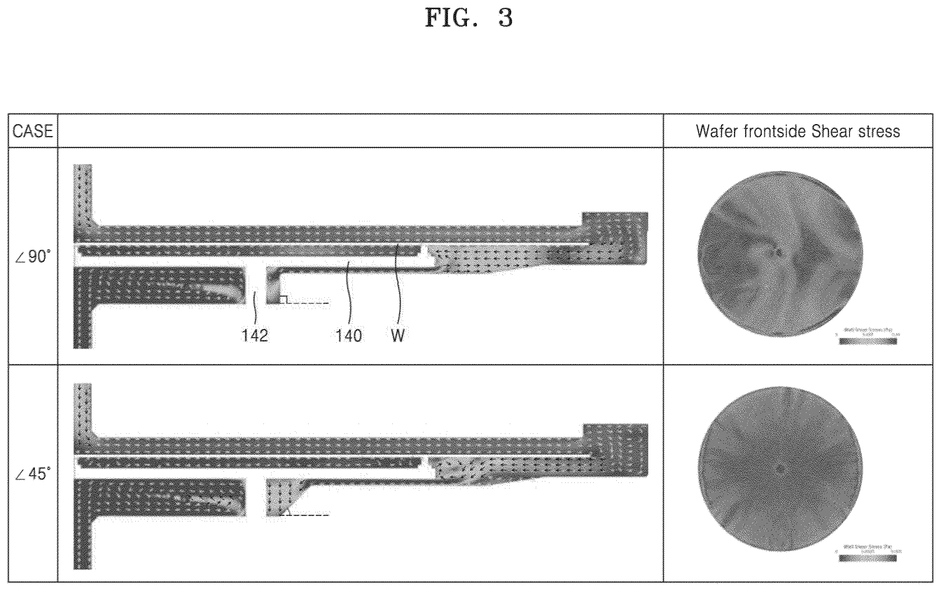

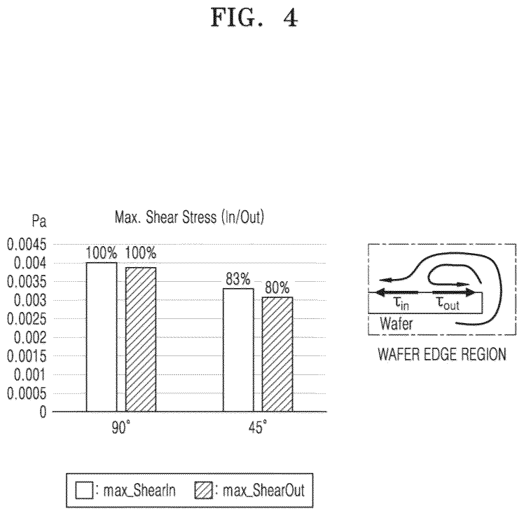

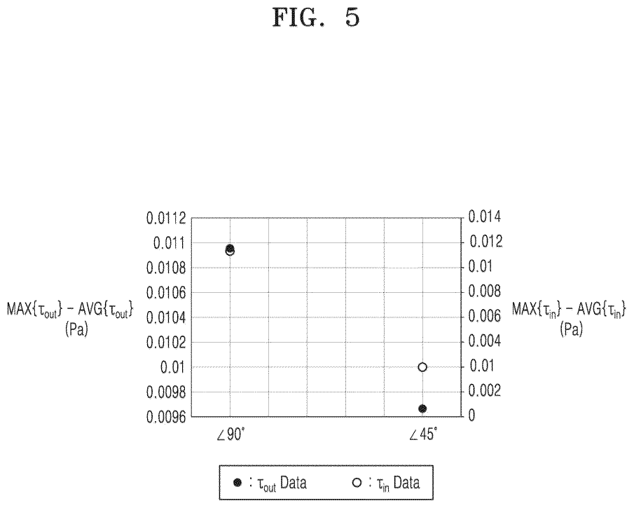

FIG. 3 illustrates simulation results depending on sizes of the first tilt angle of the substrate processing apparatus 1 according to one or more embodiments. FIG. 4 is a graph illustrating shear stresses, which are obtained from the simulation results of FIG. 3, in an edge region of a substrate depending on sizes of the first tilt angle. FIG. 5 is a graph illustrating a difference between the greatest value and an average value of the shear stresses, which are obtained from the simulation results of FIG. 3, in the edge region of the substrate depending on sizes of the first tilt angle.

FIG. 3 illustrates results of simulations separately performed in a case where the first tilt angle A1 illustrated in FIGS. 1 and 2A is 90 degrees and a case where the first tilt angle A1 is 45 degrees. A simulation diagram on the left side of FIG. 3 illustrating the right side of a cross-section of the substrate processing apparatus 1 illustrates a flow of fluid, and the entire flow of fluid may be seen from the arrows.

A shear stress of a front surface of a wafer on the right side of FIG. 3 is for analyzing the shear stress applied to various patterns formed on the front surface of the substrate W from the simulation.

FIG. 4 is a graph illustrating the greatest shear stress indicated by the simulation results of FIG. 3, when the first tilt angle A1 is 90 degrees, and when the first tilt angle A1 is 45 degrees. In the one or more embodiments, the substrate W may be referred to as a wafer.

A front surface of the wafer may be provided with patterns formed through various processes. For example, photoresist patterns may be formed on the wafer, or patterns of semiconductor devices may be formed on the wafer by performing etching and deposition processes.

Due to the shape of the processing space 101 of the substrate processing apparatus 1, a flow of the processing fluid may change significantly in a wafer edge region which is an outer edge of the substrate W. For example, referring to FIG. 3, it can be seen that the processing fluid is directed to the right near an upper surface of the substrate W in an edge region of the substrate W. In addition, it can be seen that the processing fluid is directed to the left near a lower surface of the substrate W in the edge region of the substrate W in FIG. 3. For example, it can be seen that a direction of the processing fluid changes in the front and rear of the substrate W. As a result, a flow, in which a direction of the processing fluid changes significantly, may occur in an edge region of the substrate W, which is a region around an outer edge of the substrate W, and in the process of continuously supplying high-pressure fluid to generate a supercritical state of the processing fluid, vortex may occur in the edge region of the substrate W.

The right side of FIG. 4 illustrates a shear stress including an inner shear stress Tin and an outer shear stress Tout occurring in the wafer edge region. The inner shear stress Tin refers to a shear stress in a direction toward the center of a wafer among shear stresses, and the outer shear stress Tout refers to a shear stress in a direction toward the outside of the wafer among the shear stresses. For example, when vortex occurs in an edge region of the substrate W, a relatively large shear stress occurs on a wafer surface, which may cause various patterns on an upper surface of the substrate W to collapse or to be damaged.

Recently, aspect ratios of semiconductor devices have been continuously increased, and critical dimensions of the semiconductor devices have also been decreased. The possibility of defects of patterns previously formed on the substrate W increases due to the shear stress applied during a drying process of the substrate W, and accordingly, there is a need to further reduce the shear stress occurring on a surface of the substrate W in an edge region of the substrate W.

The graph of FIG. 4 illustrates the greatest inner shear stress and outer shear stress, based on a case where the first tilt angle A1 is 90 degrees. Accordingly, a case where the first tilt angle A1 is 90 degrees is illustrated as a case where the shear stress is 100%. When the first tilt angle A1 is 90 degrees, the greatest inner shear stress is measured to be about 0.04 Pa, and the greatest outer shear stress is measured to be about 0.0037 Pa. Similarly, when the first tilt angle A1 is 45 degrees, the greatest inner shear stress is measured to be about 0.033 Pa, and the greatest outer shear stress is measured to be about 0.0031 Pa. The greatest inner shear stress when the first tilt angle A1 is 45 degrees is at the level of 83% of the greatest inner shear stress when the first tilt angle A1 is 90 degrees. It can be seen that the greatest outer shear stress when the first tilt angle A1 is 45 degrees is about 80% of the greatest outer shear stress when the first tilt angle A1 is 90°.

Compared to when the first tilt angle A1 is 90 degrees, when the first tilt angle A1 is 45 degrees, the sizes of the greatest inner shear stress and the greatest outer shear stress in the edge region of the wafer are reduced. The smaller the greatest value of the shear stress applied to the wafer edge region is, the less the possibility that patterns of the substrate W are damaged by the processing fluid is. Accordingly, compared to when the first tilt angle A1 is 90 degrees, when the first tilt angle A1 is 45 degrees, the possibility of patterns on the substrate W being damaged by the processing fluid may be reduced. For example, the substrate processing apparatus 1 according to the one or more embodiments may reduce the possibility of damage to a substrate by improving a flow distribution of the processing fluid in the processing space 101.

FIG. 5 is a graph illustrating a difference between the greatest outer shear stress angles and an average outer shear stress on respective angles and a difference between the greatest inner shear stress and an average inner shear stress on the respective angles when the first tilt angle A1 is 90 degrees and when the first tilt angle A1 is 45 degrees.

When the first tilt angle A1 is 90 degrees, the difference between the greatest outer shear stress and the average outer shear stress, which is illustrated as a black dot in the graph of FIG. 5, is calculated to be about 0.01088 Pa. When the first tilt angle A1 is 90 degrees, the difference between the greatest inner shear stress and the average inner shear stress, which is illustrated as a white dot, is calculated to be about 0.0113 Pa.

When the first tilt angle A1 is 45 degrees, the difference between the greatest inner shear stress and the average inner shear stress, which is illustrated as a white dot, is calculated to be about 0.00964 Pa. When the first tilt angle A1 is 45 degrees, the difference between the greatest inner shear stress and the average inner shear stress, which is illustrated as a white dot, is calculated to be about 0.01 Pa.

The difference between the greatest shear stress and the average shear stress described above may indicate the degree of flow imbalance in a wafer edge region in the processing space 101. As described above, patterns formed on the substrate W may collapse due to the shear stress of processing fluid. When the shear stress of processing fluid is not relatively constant but is applied to patterns on the substrate W as shear stress with a large deviation between the greatest value and the average value, the possibility of the patterns on the substrate W being damaged by the processing fluid may increase. For example, the smaller the deviation between the greatest value and the average value of the shear stresses applied to a wafer edge region is, the less the possibility that patterns of the substrate W are damaged by the processing fluid is.

Accordingly, in the substrate processing apparatus 1 according to the one or more embodiments, the first tilted surface 123 having a first tilt angle A1 that is not perpendicular to the chamber lower surface 120S is provided. Accordingly, the shear stress that the processing fluid acts on a pattern formed on an upper surface of the substrate W in a wafer edge region may be reduced, and the deviation between the greatest value and an average value of the shear stresses may be reduced, resulting in reduction of damage to the substrate W which may occur during a drying process of the substrate W. For example, the substrate processing apparatus 1 according to the one or more embodiments may reduce the possibility of damage to a substrate by improving a flow distribution of the processing fluid in the processing space 101.

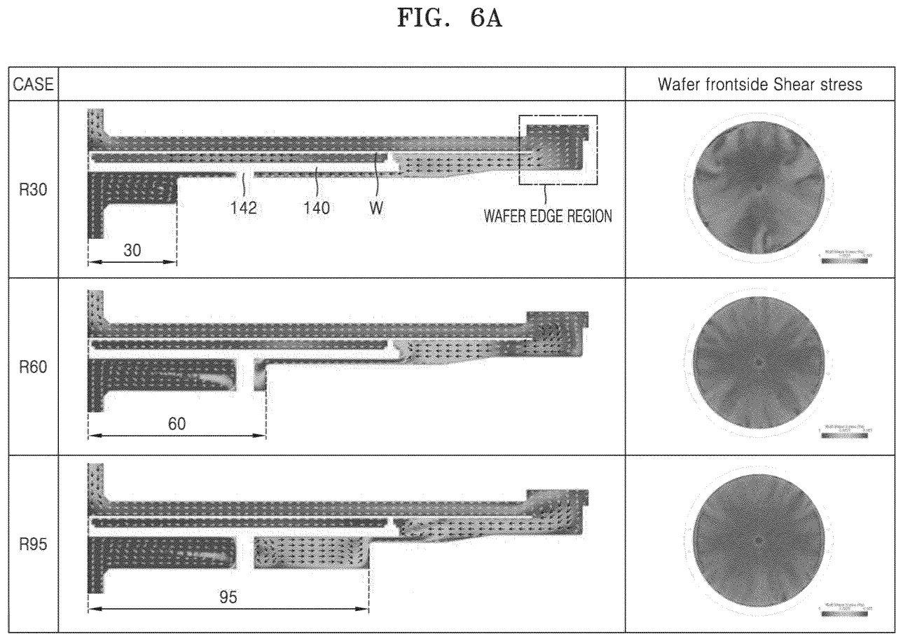

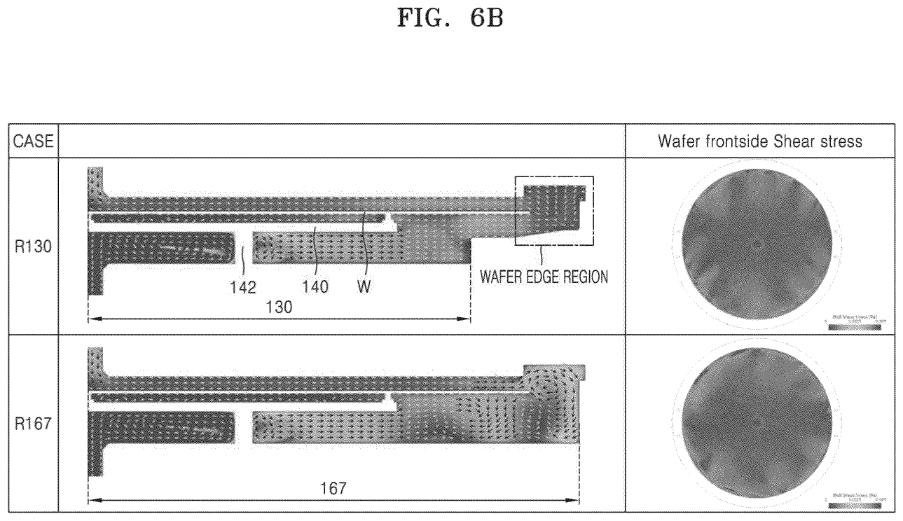

FIG. 6A illustrates simulation results depending on sizes of the first radius R1 of the substrate processing apparatus 1 according to the one or more embodiments. FIG. 6B illustrates simulation results depending on sizes of the first radius R1 of the substrate processing apparatus 1 according to the one or more embodiments.

Referring to FIGS. 6A and 6B, simulation pictures on the left sides of FIGS. 6A and 6B illustrate the flow of processing fluid in the processing space 101 with respect to the right cross-section of the substrate processing apparatus 1. The simulation pictures on the right sides of FIGS. 6A and 6B illustrate simulation results showing shear stress distributions of a front surface of the substrate W and illustrate the shear stress acting on the entire surface of the substrate W where the patterns are formed.

The simulation results depending on sizes of the first radius R1 (see FIGS. 1 and 2A) are illustrated for each of cases where the first radius R1 is 30 mm, 60 mm, 95 mm, 130 mm, and 167 mm. As described with reference to FIG. 4, due to the shape of the substrate processing apparatus 1, the flow of processing fluid may change greatly in a wafer edge region, which is an outer edge of the substrate W. Due to a difference in size of the first radius R1, when the first radius R1 is 30 mm, the second connection point 123B is located to be closer to the center than the plate support 142. When the first radius R1 is 60 mm and when the first radius R1 is 95 mm, the second connection point 123B is located farther from the center than the plate support 142. When the first radius R1 is 130 mm, the second connection point 123B is located farther from the center than an outer edge of the plate support 142. When the first radius R1 is 167 mm which is the greatest, the second connection point 123B does not appear, and the shape of the chamber lower surface 120S may entirely have a shape parallel to the substrate W.

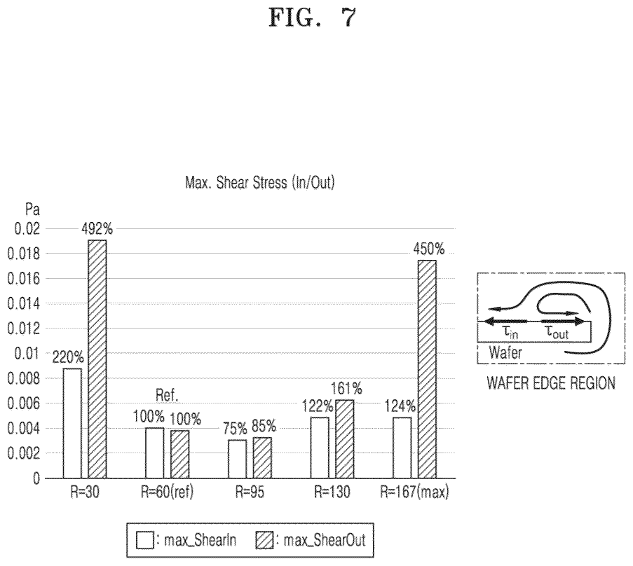

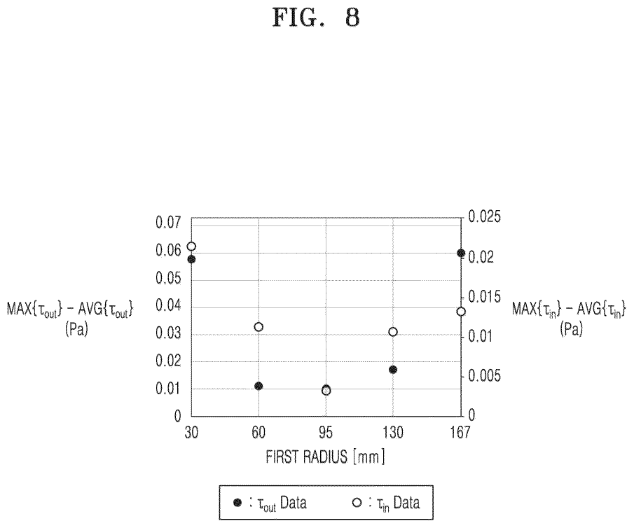

FIG. 7 is a graph illustrating shear stresses in an edge region of a substrate depending on sizes of the first radius R1 obtained from the simulation results of FIGS. 6A and 6B. FIG. 8 is a graph illustrating a difference between the greatest value and an average value of shear stresses in an edge region of a substrate depending on sizes of the first radius R1 obtained from the simulation result of FIG. 3.

Referring to FIG. 7, the graph illustrates the greatest inner shear stress and the greatest outer shear stress when the first radius R1 is 30 mm, 60 mm, 95 mm, 130 mm, or 167 mm, based on the greatest inner shear stress and the greatest outer shear stress when the first radius R1 is 60 mm.

When the first radius R1 is 60 mm, the greatest inner shear stress is measured to be about 0.004 Pa, and the greatest outer shear stress is measured to be 0.0038 Pa. When the first radius R1 is 30 mm, the greatest inner shear stress is measured to be about 0.0088 Pa, and the greatest outer shear stress is measured to be 0.019 Pa. This is a value corresponding to about 220% of the greatest inner shear stress and about 492% of the greatest outer shear stress when the first radius R1 is 60 mm. When the first radius R1 is 95 mm, the greatest inner shear stress is measured to be about 0.0031 Pa, and the greatest outer shear stress is measured to be 0.0033 Pa. This is a value corresponding to about 75% of the greatest inner shear stress and about 85% of the greatest outer shear stress when the first radius R1 is 60 mm. When the first radius R1 is 130 mm, the greatest inner shear stress is measured to be about 0.0047 Pa, and the greatest outer shear stress is measured to be about 0.0062 Pa. This is a value corresponding to about 122% of the greatest inner shear stress and about 161% of the greatest outer shear stress when the first radius R1 is 60 mm. When the first radius R1 is 167 mm, the greatest inner shear stress is measured to be about 0.0048 Pa, and the greatest outer shear stress is measured to be about 0.0173 Pa. This is a value corresponding to about 124% of the greatest inner shear stress and about 450% of the greatest outer shear stress when the first radius R1 is 60 mm.

In the graph illustrating the greatest inner shear stress and the greatest outer shear stress in FIG. 7, it can be seen that, when the first radius R1 is 60 mm to 95 mm, the shear stress in the wafer edge region is relatively small. When the first radius R1 is 60 mm to 95 mm, the smaller the first radius R1 is, the less the possibility that patterns of the substrate W are damaged by the processing fluid is.

Comparing the shape formed when the first radius R1 is 60 mm to 95 mm as illustrated in FIG. 6A with the graph illustrated in FIG. 7, when the first radius R1 is greater than a distance from the center of the plate support 142, and when the first radius R1 is less than an outer diameter of the block plate 140, it can be seen that the shear stress in a wafer edge region is relatively small. For example, when the first radius R1 is greater than the distance from the center of the plate support 142, and when the first radius R1 is less than the outer diameter of the block plate 140, the possibility that patterns of the substrate W are damaged by the processing fluid may be reduced. For example, the substrate processing apparatus 1 according to the one or more embodiments may reduce the possibility of damage to a substrate by improving a flow distribution of processing fluid in the processing space 101.

Referring to FIG. 8, the graph illustrates a difference between the greatest outer shear stress and an average outer shear stress and a difference between the greatest inner shear stress and the average inner shear stress acting on a front surface of the substrate W in a wafer edge region for each size when the first radius R1 is 30 mm, 60 mm, 95 mm, 130 mm, or 167 mm.

When the first radius R1 is 30 mm, the difference between the greatest outer shear stress and the average outer shear stress which is illustrated as a black dot in the graph of FIG. 8 is calculated to be about 0.0058 Pa. When the first radius R1 is 30 mm, the difference between the greatest inner shear stress and the average inner shear stress which is illustrated as a white dot is calculated to be about 0.022 Pa.

When the first radius R1 is 60 mm, the difference between the greatest outer shear stress and the average outer shear stress which is illustrated as a black dot is calculated to be about 0.011 Pa, and the difference between the greatest inner shear stress and the average inner shear stress which is illustrated as a white dot is calculated to be about 0.012 Pa.

When the first radius R1 is 95 mm, the difference between the greatest outer shear stress and the average outer shear stress which is illustrated as a black dot is calculated to be about 0.01 Pa, and the difference between the greatest inner shear stress and the average inner shear stress which is illustrated as a white dot is calculated to be about 0.003 Pa.

When the first radius R1 is 130 mm, the difference between the greatest outer shear stress and the average outer shear stress which is illustrated as a black dot is calculated to be about 0.017a, and the difference between the greatest inner shear stress and the average inner shear stress which is illustrated as a white dot is calculated to be about 0.011 Pa.

When the first radius R1 is 167 mm which is the greatest, the difference between the greatest outer shear stress and the average outer shear stress which is illustrated as a black dot is calculated to be about 0.021 Pa, and the difference between the greatest inner shear stress and the average inner shear stress which is illustrated as a white dot is calculated to be about 0.014 Pa.

The difference between the greatest shear stress and the average shear stress described above may indicate the degree of flow imbalance in a wafer edge region in the processing space 101. The smaller a deviation between the greatest value and an average value of the shear stresses applied to a wafer edge region is, the less the possibility that patterns of the substrate W is damaged by the processing fluid is.

In the graph of FIG. 8, it can be seen that, when the first radius R1 is 60 mm to 95 mm, a difference between the greatest value and an average value of the shear stresses in a wafer edge region is relatively small. Accordingly, when the first radius R1 is 60 mm to 95 mm, the possibility that patterns of the substrate W are damaged by the processing fluid may be reduced.

Comparing the shape formed when the first radius R1 is 60 mm to 95 mm as illustrated in FIG. 6A with the graph illustrated in FIG. 7, when the first radius R1 is greater than a distance from the center of the plate support 142, and when the first radius R1 is less than an outer diameter of the block plate 140, it can be seen that a difference between the greatest value and an average value of the shear stresses in a wafer edge region is relatively small. For example, when the first radius R1 is greater than the distance from the center of the plate support 142, and when the first radius R1 is less than the outer diameter of the block plate 140, the possibility that patterns of the substrate W are damaged by the processing fluid may be reduced.

Accordingly, in the substrate processing apparatus 1 according to the one or more embodiments, when the first radius R1 is 60 mm to 95 mm, or when the first radius R1 is greater than a distance from the center of the plate support 142 and is less than an outer diameter of the block plate 140 as described above with reference to FIGS. 1 and 2A, the processing fluid is reduced in deviation between the greatest value and an average value of the shear stresses in a wafer edge region, and thus, damage to the substrate W that may occur during a drying process of the substrate W may be reduced.

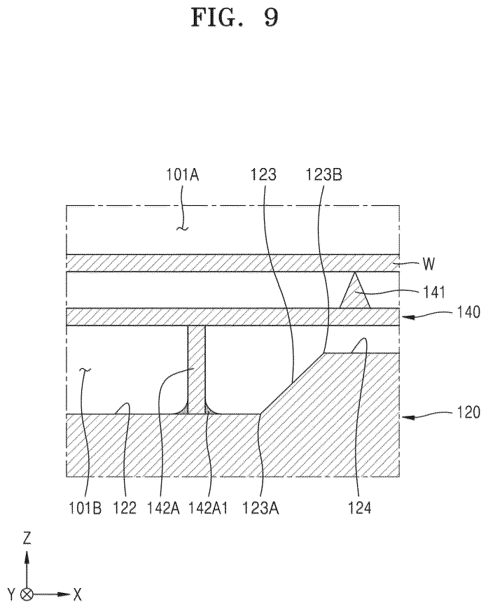

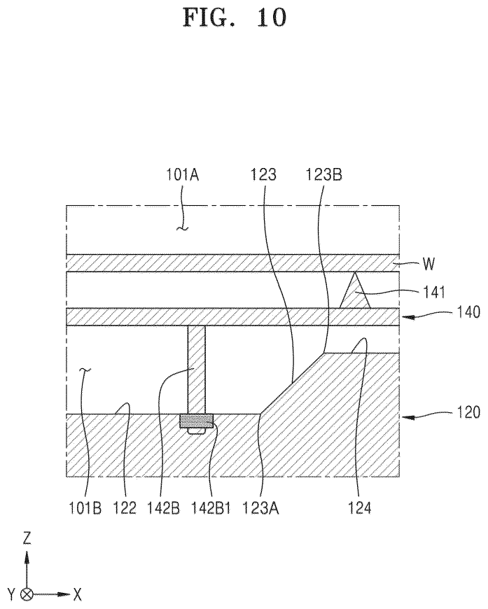

FIG. 9 is an enlarged cross-sectional view of a part of the substrate processing apparatus 1 according to the one or more embodiments. FIG. 10 is an enlarged cross-sectional view of a part of the substrate processing apparatus 1 according to the one or more embodiments.

Referring to FIG. 9, a plate support 142A may be attached to the first surface 122, and accordingly, the plate support 142A may be integrated with the first surface 122. The block plate 140 may be fixed to the lower container 120 through a pillar connection portion 142A1 of the plate support 142A. For example, the pillar connection portion 142A1 may be a trace of adhesive or welding that does not affect processes.

Referring to FIG. 10, a plate support 142B may be fixed onto the first surface 122, and thus, the plate support 142B may be integrated with the first surface 122. For example, the plate support 142B may be coupled to the lower container 120 through a fastening portion 142B1 buried in the first surface 122 of the lower container 120, and accordingly, the block plate 140 may be fixed to the lower container 120. For example, the fastening portion 142B1 may be a nut with an inner thread, and a screw thread that may be fastened to an inner screw thread of the fastening portion 142B1 may be provided in one end of the plate support 142B.

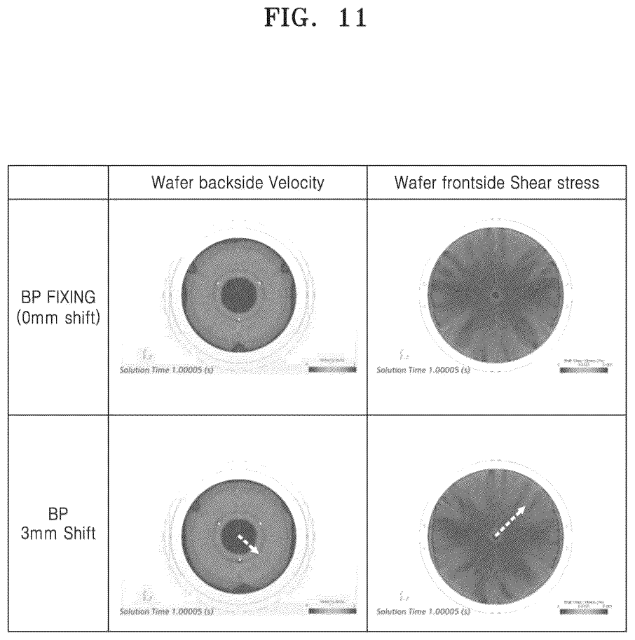

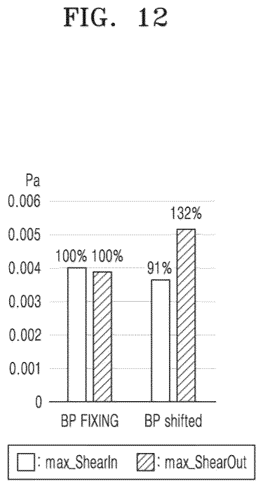

FIG. 11 illustrates simulation results for comparing a flow when the block plate (BP) 140 is fixed with a flow when the block plate 140 deviates from a normal position. FIG. 12 is a graph illustrating a shear stress acting on a front surface of a wafer which is obtained from the simulation result of FIG. 11.

Referring to FIG. 11, the upper portion of FIG. 11 shows simulation results indicating a flow speed distribution on a rear side of a wafer and shear stresses on a front side of the wafer when the block plate 140 is in a correct position, that is, when the block plate 140 is moved by 0 mm. The lower portion of FIG. 11 shows simulation results indicating a flow speed distribution on a rear side of the wafer and shear stresses on a front side of the wafer when the block plate 140 is not in the correct position, that is, when the block plate 140 is moved laterally by 3 mm. Arrows illustrated in FIG. 11 indicate directions in which the block plate 140 is moved laterally by 3 mm.

Referring to FIG. 12, the graph illustrates the greatest outer shear stress and the greatest inner shear stress acting on a wafer edge region when the block plate 140 is fixed and does not move, and when the block plate 140 is moved by 3 mm which is calculated from the simulation results of FIG. 11.

When the block plate 140 is fixed and does not move as illustrated in FIGS. 9 and 10, the greatest inner shear stress is calculated to be about 0.004 Pa and the greatest outer shear stress is calculated to be about 0.0038 Pa. When the block plate 140 is not fixed and moved by 3 mm, the greatest inner shear stress is calculated to be about 0.0036 Pa and the greatest outer shear stress is calculated to be about 0.0051 Pa. Based on a case where the block plate 140 is fixed and does not move, the greatest inner shear stress is calculated to be about 91% and the greatest outer shear stress is calculated to be about 132%.

Referring to FIGS. 1 and 2A, in a drying process of the substrate W using supercritical fluid, the flow of high-pressure processing fluid continues in the processing space 101. Accordingly, when the block plate 140 in the processing space 101 is not fixed to the processing space 101, the block plate 140 may be moved by the flow of high-pressure processing fluid. When a symmetrical shape of the inside of the processing space 101 is not formed due to movement of the block plate 140, a greater shear stress may be applied to the substrate W due to non-uniformity in a flow speed and flow rate of the processing fluid flowing inside the processing space 101, compared to a case where the symmetrical shape is maintained.

In the substrate processing apparatus 1 according to the one or more embodiments, the block plate 140 is fixed to the lower container 120 to maintain a symmetrical shape of the processing space 101, and thus, uniformity of the processing fluid flowing inside the processing space 101 may be obtained. Accordingly, the block plate 140 is fixed to the lower container 120, and thus, damage of patterns occurring in an edge region of the substrate W may be reduced. For example, the substrate processing apparatus 1 according to the one or more embodiments may reduce the possibility of damage to a substrate by improving a flow distribution of the processing fluid in the processing space 101.

The substrate processing apparatus according to one or more embodiments may reduce vortex occurring in a wafer edge region by improving the shape of a processing space. Also, a flow distribution of fluid in a processing space may be improved by a fixed block plate. By improving vortex and a flow distribution, shear stress applied to patterns in a wafer edge region due to supercritical fluid may be reduced, and thus, the possibility damage of a wafer, such as damage of patterns of the wafer, may be reduced.

As described above, embodiments are described with reference to the attached drawings, and may be modified into other specific forms without changing the technical idea or essential features. Therefore, the embodiments described above are illustrative in all respects and should not be understood as limiting.

While embodiments have been described with reference to the figures, it will be understood by those of ordinary skill in the art that various changes in form and details may be made therein without departing from the spirit and scope as defined by the following claims and their equivalents.

What is claimed is:

1. A substrate processing apparatus comprising:
a processing container comprising an upper container, a lower container, and a processing space inside the upper container and the lower container;
a support pin in the processing space and configured to support a substrate;
a block plate comprising an upper surface, the support pin being on the upper surface of the block plate;
a plate support in the lower container and configured to support a lower surface of the block plate opposite to the upper surface of the block plate;
a first conduit line in the upper container;
a second conduit line in the lower container; and
a fluid supply device configured to supply processing fluid in a supercritical state to the processing space through the first conduit line,
wherein a chamber lower surface of the lower container, in contact with the processing space, comprises a first surface, a first tilted surface, and a second surface extending sequentially from a center of the processing space,
wherein a vertical level of the second surface is higher than a vertical level of the first surface, and
wherein a first tilt angle between the first tilted surface and the first surface is an acute angle.

2. The substrate processing apparatus of claim 1, wherein a distance between the plate support and a first center line is less than a first radius,
wherein the first radius is a radius from the first center line to a first connection point in which the first surface contacts the first tilted surface, and
wherein the first center line extends vertically from a center of the upper container to a center line of the lower container.

3. The substrate processing apparatus of claim 2, wherein a second radius is less than a radius of the block plate, and
wherein the second radius is a radius from the first center line to a second connection point in which the first tilted surface contacts the second surface.

4. The substrate processing apparatus of claim 3, wherein the first radius is 60 mm to 95 mm.

5. The substrate processing apparatus of claim 3, wherein the first surface, the second surface, and the substrate are parallel to each other.

6. The substrate processing apparatus of claim 3, wherein the plate support is integrated with the lower container.

7. The substrate processing apparatus of claim 3, wherein the chamber lower surface further comprises a second tilted surface and a third surface sequentially extending from the second surface.

8. The substrate processing apparatus of claim 7, wherein the first surface, the second surface, and the third surface are parallel to each other, and
wherein an angle between the second tilted surface and the second surface is an acute angle.

9. The substrate processing apparatus of claim 1, wherein the first tilt angle is greater than a first reference angle, and
wherein the first reference angle between the first surface and an extension line extending from the plate support to an outer diameter of the block plate is an acute angle.

10. The substrate processing apparatus of claim 9, wherein the plate support is fastened to a support fastening portion buried in the lower container, the plate support being integrated with the lower container.

11. The substrate processing apparatus of claim 1, wherein the first tilt angle is greater than a second reference angle, and
wherein the second reference angle between the first surface and an extension line extending from a first connection point, in which the first surface contacts the first tilted surface, to an outer diameter of the block plate is an acute angle.

12. The substrate processing apparatus of claim 1, wherein a first height, which is a vertical distance between the first surface and the block plate, is greater than a second height, which is a vertical distance between the second surface and the block plate, and
wherein a third height, which is a vertical distance between the substrate and the second surface, is greater than the second height.

13. The substrate processing apparatus of claim 12, wherein the second height is 0.1 to 0.25 times the first height, and the third height is 5 to 8 times the second height.

14. The substrate processing apparatus of claim 1, wherein the first conduit line and the second conduit line are respectively at a center of the upper container and a center of the lower container, and
wherein the first conduit line is on a same line as the second conduit line.

15. A substrate processing apparatus comprising:
a processing container comprising an upper container, a lower container, and a processing space inside the upper container and the lower container;
a support pin in the processing space and configured to support a substrate;
a block plate comprising an upper surface, the support pin being on the upper surface of the block plate;
a plate support in the lower container and configured to support a lower surface of the block plate opposite to the upper surface of the block plate;
a first conduit line in the upper container;
a second conduit line in the lower container; and
a fluid supply device configured to supply processing fluid in a supercritical state to the processing space through the first conduit line,
wherein a chamber lower surface of the lower container, in contact with the processing space, comprises a first surface, a first tilted surface, and a second surface extending sequentially from a center of the processing space,
wherein a vertical level of the second surface is higher than a vertical level of the first surface,
wherein a first tilt angle between the first tilted surface and a horizontal surface is an acute angle, and
wherein the first tilted surface is farther from a center of the lower container than the plate support.

16. The substrate processing apparatus of claim 15, wherein a second connection point is closer to the center of the lower container than an outer diameter of the block plate, and
wherein the first tilted surface contacts the second surface at the second connection point.

17. The substrate processing apparatus of claim 16, wherein an extension line of the first tilted surface contacts the block plate.

18. The substrate processing apparatus of claim 16, wherein the plate support is integrated with the lower container.

19. A substrate processing apparatus comprising:
a processing container comprising an upper container, a lower container, and a processing space inside the upper container and the lower container;
a support pin in the processing space and configured to support a substrate;
a block plate comprising an upper surface, the support pin being on the upper surface of the block plate;
a plate support in the lower container and configured to support a lower surface of the block plate opposite to the upper surface of the block plate;
a first conduit line in the upper container;
a second conduit line in the lower container;
a fluid supply device configured to supply processing fluid in a supercritical state to the processing space through the first conduit line; and
an upper substrate support in the upper container and configured to support a side portion of the substrate,
wherein a chamber lower surface of the lower container, in contact with the processing space, comprises a first surface, a first tilted surface, a second surface, a second tilted surface, and a third surface extending sequentially from a center of the processing space,
wherein a vertical level of the second surface is higher than a vertical level of the first surface,
wherein a first tilt angle between the first tilted surface and the first surface is an acute angle, and an angle between the second tilted surface and the second surface is an acute angle,
wherein a distance between the plate support and a first center line is less than a first radius, the first center line being a virtual line vertically extending from a center of the upper container to a center line of the lower container,
wherein the first radius is a radius from the first center line to a first connection point in which the first surface contacts the first tilted surface,
wherein a second radius is less than a radius of the block plate,
wherein the second radius is a radius from the first center line to a second connection point where the first tilted surface contacts the second surface,
wherein the first surface, the second surface, and the third surface are parallel to each other,
wherein the plate support is integrated with the lower container,
wherein the first tilt angle is greater than a first reference angle,
wherein the first reference angle between the first surface and an extension line extending from the plate support to an outer diameter of the block plate is an acute angle, and
wherein the first conduit line and the second conduit line are respectively at a center of the upper container and a center of the lower container and are on a same line.

20. The substrate processing apparatus of claim 19, wherein a first height, which is a vertical distance between the first surface and the block plate, is greater than a second height, which is a vertical distance between the second surface and the block plate,
wherein a third height, which is a vertical distance between the substrate and the second surface, is greater than the second height,
wherein the first radius is 60 mm to 95 mm,
wherein the first tilt angle is greater than a second reference angle, and
wherein the second reference angle is between the first surface and an extension line extending from the first connection point to an outer edge of the block plate.
